(19) United States
(12) Patent Application Publication
(10) Pub. No.: US 2015/0079502 A1
(43) Pub. Date: Mar. 19, 2015

(54) MASK BLANK AND METHOD OF MANUFACTURING A TRANSFER MASK

(71) Applicant: HOYA CORPORATION, Shinjuku-ku, Tokyo (JP)

(72) Inventors: Toshiyuki Suzuki, Tokyo (JP); Takeyuki Yamada, Tokyo (JP)

(73) Assignee: HOYA CORPORATION, Shinjuku-ku, Tokyo (JP)

(21) Appl. No.: 14/384,953

(22) PCT Filed: Feb. 2, 2013
(86) PCT No.: PCT/JP2013/052801

§ 371 Date: Sep. 12, 2014

(30) Foreign Application Priority Data
Mar. 14, 2012 (JP) 2012-057489

(51) Int. Cl. G03F 1/38

(52) U.S. Cl. CPC G03F 1/38
USPC 430/5

(57) ABSTRACT

Provided is a mask blank having a structure including a thin film on a substrate, wherein the thin film is made of a material containing one or more elements selected from tantalum, tungsten, zirconium, hafnium, vanadium, niobium, nickel, titanium, palladium, molybdenum, and silicon, and wherein the normalized secondary ion intensity of at least one or more ions selected from a calcium ion, a magnesium ion, and an aluminum ion is 1.0×10⁻³ or less when a surface of the thin film is measured by time-of-flight secondary ion mass spectrometry (TOF-SIMS) under measurement conditions of a primary ion species of Bi₃⁺⁺, a primary accelerating voltage of 30 kV, and a primary ion current of 3.0 nA.

### TECHNICAL FIELD

This invention relates to a mask blank and a method of manufacturing a transfer mask.

### BACKGROUND ART

Generally, fine pattern formation is carried out by photolithography in the manufacturing process of a semiconductor device or the like. In a fine pattern transfer process where the photolithography is carried out, a transfer mask is used. This transfer mask is generally manufactured by forming a desired fine pattern in a light-shielding film of a mask blank as an intermediate product. Consequently, the properties of the light-shielding film of the mask blank as the intermediate product almost exactly determine the performance of the transfer mask.

In recent years, there has been developed a mask blank comprising a light-shielding film made of a tantalum-based material and the performance of a transfer mask manufactured using such a mask blank has been evaluated. JP-A-2006-78825 (Patent Document 1) discloses that a Ta metal film has an extinction coefficient (light absorptivity) equal to or greater than that of a Cr metal film for light having a wavelength of 193 nm which is used in ArF excimer laser exposure. Further, as a transfer mask blank that enables precise formation of a fine transfer mask pattern by reducing the load to a resist which is used as a mask in the transfer mask pattern formation, Patent Document 1 discloses a transfer mask blank comprising a light-shielding layer in the form of a metal film that is not substantially etched by oxygen-containing chlorine-based ((Cl+O)-based) dry etching, but can be etched by oxygen-free chlorine-based (Cl-based) dry etching and fluorine-based (F-based) dry etching, and an antireflection layer in the form of a metal compound film that is not substantially etched by oxygen-free chlorine-based (Cl-based) dry etching, but can be etched by at least one of oxygen-containing chlorine-based ((Cl+O)-based) dry etching and fluorine-based (F-based) dry etching.

### PRIOR ART DOCUMENT

### Patent Document

Patent Document 1: JP-A-2006-78825

### SUMMARY OF THE INVENTION

### Problem to be Solved by the Invention

Normally, a mask blank is cleaned using cleaning water or a cleaning liquid containing a surfactant for the purpose of removing oil droplets, particles, and so on present on a film surface. Further, in order to prevent the occurrence of stripping or collapse of a fine pattern in a process after forming a resist film, a surface treatment for reducing the surface energy of the mask blank may be carried out before coating the resist film. As the surface treatment in this case, the surface of the mask blank may be, for example, alkyl-silylated with hexamethyldisilazane (HMDS) or another organic silicon-based surface treatment agent.

A defect inspection of the mask blank is carried out before or after forming the resist film on its surface. Then, a transfer mask is manufactured by etching the mask blank satisfying a desired specification (quality). In an etching process of etching the mask blank described in Patent Document 1, a resist film formed on the mask blank is subjected to writing, development, and rinsing and, after forming a resist pattern, the antireflection layer is etched using the resist pattern as a mask, thereby forming an antireflection layer pattern. In the etching of the antireflection layer, an oxygen-containing chlorine-based gas or a fluorine-based gas is used. Then, the light-shielding layer is etched using the antireflection layer pattern as a mask, thereby forming a light-shielding layer pattern. In the etching of the light-shielding layer, an oxygen-free chlorine-based gas is used. Finally, the resist film is removed so that a transfer mask is completed. The completed transfer mask is subjected to an inspection using a mask defect inspection apparatus to check whether or not there is a black or white defect and, if the defect is detected, the defect is corrected using a correction technique such as EB irradiation.

There has been a problem that when a transfer mask is manufactured using a mask blank comprising a light-shielding film made of a tantalum-based material, more black defects occur than when a transfer mask is manufactured using a mask blank comprising a light-shielding film made of a chromium-based material. On the mask blank comprising the light-shielding film made of the tantalum-based material, the number of defects is within an allowable range according to a defect inspection carried out before resist coating. That is, it has been found that micro black defects which are not detected in the defect inspection of the mask blank but are first detected in a defect inspection after the transfer mask is manufactured using the mask blank are present in a certain number. The micro black defects are present in spots on a surface of a substrate, each having a size of 20 to 100 nm with a height corresponding to the thickness of the thin film, and are first recognized in the manufacture of the transfer mask for the semiconductor design rule DRAM half-pitch 32 nm and beyond. The micro black defects should all be removed/corrected because they act as serious defects in the manufacture of a semiconductor device. However, if the number of the defects exceeds 50, the load of defect correction is so large as to make it practically difficult to perform the defect correction. Further, with the increasing integration of semiconductor devices in recent years, the defect removal/correction is reaching its limit due to complication (e.g. OPC pattern), miniaturization (e.g. Sub-Resolution Assist Feature such as assist bar), and narrowing of a thin film pattern formed in a transfer mask, which has been a problem.

This invention has been made under these circumstances and has an object to provide a mask blank that can suppress the occurrence of black defects of a transfer mask.

### Means for Solving the Problem

As a result of investigating the cause of the occurrence of the micro black defects of the mask described above, the present inventors have found that one cause is latent defects of the mask blank which are not detected in the defect inspection of the mask blank.

Then, the present inventors have found that the latent defects of the mask blank occur due to the presence of a substance that causes inhibition of etching, such as calcium, on a surface of the mask blank.

As means for solving the above-mentioned problems, this invention has the following structures.

(Structure 1)

A mask blank having a structure comprising a thin film on a substrate, wherein the thin film is made of a material containing one or more elements selected from tantalum, tungsten, zirconium, hafnium, vanadium, niobium, nickel, titanium, palladium, molybdenum, and silicon, and

wherein a normalized secondary ion intensity of at least one or more ions selected from a calcium ion, a magnesium ion, and an aluminum ion is 1.0×10⁻³ or less when a surface of the thin film is measured by time-of-flight secondary ion mass spectrometry (TOF-SIMS) under measurement conditions of a primary ion species of Bi₃⁺⁺, a primary accelerating voltage of 30 kV, and a primary ion current of 3.0 nA.

The normalized secondary ion intensity referred to in this specification is a numerical value calculated by dividing the number of target ions (calcium ions or the like) by the total number of secondary ions, counted in a measurement range, which were emitted from a surface of a thin film by irradiating primary ions to the surface of the thin film.

(Structure 2)

The mask blank according to structure 1, wherein the thin film is made of a material containing tantalum.

(Structure 3)

The mask blank according to structure 2, wherein the thin film comprises as a surface layer an oxide layer containing oxygen.

(Structure 4)

The mask blank according to structure 2, wherein the thin film comprises a laminated structure having a lower layer and an upper layer from a substrate side and the upper layer contains oxygen.

(Structure 5)

The mask blank according to any of structures 1 to 4, wherein the thin film is provided to form a thin film pattern by dry etching using an etching gas containing fluorine or an etching gas containing chlorine.

(Structure 6)

The mask blank according to any of structures 1 to 5, wherein the normalized secondary ion intensity is measured under a measurement condition that a primary ion irradiation region is a square region with a side of 200 μm.

(Structure 7)

The mask blank according to structure 1, wherein the at least one or more ions selected from the calcium ion, the magnesium ion, and the aluminum ion are substances each of which becomes a factor to cause inhibition of etching upon forming a pattern in the thin film by dry etching using an etching gas containing fluorine or an etching gas containing chlorine.

(Structure 8)

The mask blank according to any of structures 1 to 7,

wherein the substrate is a glass substrate having transparency for exposure light, and

wherein the thin film is used to form a transfer pattern upon manufacturing a transfer mask from the mask blank.

(Structure 9)

The mask blank according to any of structures 1 to 8,

wherein a multilayer reflective film having a function of reflecting exposure light is provided between the substrate and the thin film, and

wherein the thin film is used to form a transfer pattern upon manufacturing a transfer mask from the mask blank.

(Structure 10)

A method of manufacturing a transfer mask, comprising:

forming a transfer pattern by dry etching in the thin film of the mask blank according to any of structures 1 to 9.

(Structure 11)

The method of manufacturing a transfer mask according to structure 10, wherein the dry etching uses an etching gas containing fluorine or an etching gas containing chlorine.

### Effect of the Invention

According to this invention, by configuring a mask blank such that the normalized secondary ion intensity of at least one or more ions selected from a calcium ion, a magnesium ion, and an aluminum ion is 1.0×10⁻³ or less when a surface of a thin film is measured by time-of-flight secondary ion mass spectrometry under a predetermined measurement condition, it is possible to suppress the occurrence of black defects when a transfer mask is manufactured by forming a pattern in the thin film by etching.

### BRIEF DESCRIPTION OF THE DRAWINGS

FIG. 1 is a cross-sectional photograph obtained by observing a micro black defect in bright field using a scanning transmission electron microscope.

FIG. 2 is a cross-sectional photograph obtained by observing an etching inhibition factor, formed on a surface of a tantalum-based mask blank, in dark field using a scanning transmission electron microscope.

FIG. 3A is a diagram for explaining the mechanism of the occurrence of a micro black defect.

FIG. 3B is a diagram for explaining the mechanism of the occurrence of the micro black defect.

FIG. 3C is a diagram for explaining the mechanism of the occurrence of the micro black defect.

FIG. 3D is a diagram for explaining the mechanism of the occurrence of the micro black defect.

FIG. 3E is a diagram for explaining the mechanism of the occurrence of the micro black defect.

FIG. 4A is a diagram for explaining the mechanism that an etching inhibition factor adheres to a surface of a tantalum-based mask blank.

FIG. 4B is a diagram for explaining the mechanism that the etching inhibition factor adheres to the surface of the tantalum-based mask blank.

FIG. 5A is a diagram for explaining the mechanism that an etching inhibition factor does not easily adhere to a surface of a chromium-based mask blank.

FIG. 5B is a diagram for explaining the mechanism that the etching inhibition factor does not easily adhere to the surface of the chromium-based mask blank.

### MODE FOR CARRYING OUT THE INVENTION

For completing a mask blank of this invention, the following test and study were carried out in order to examine the cause of the occurrence of micro black defects on a transfer mask.

In order to examine the cause of the occurrence of micro black defects on a transfer mask, two kinds of mask blanks were prepared. One was the mask blank formed with a thin film made of a tantalum-based material while the other was the mask blank formed with a thin film made of a chromium-based material.

As the mask blank formed with the thin film made of the tantalum-based material, there was prepared a binary mask blank having on a transparent substrate a laminated structure of a TaN light-shielding layer (thickness: 42 nm) substantially composed of tantalum and nitrogen and a TaO antireflection layer (thickness: 9 nm) substantially composed of tantalum and oxygen (hereinafter, this binary mask blank will be referred to as a tantalum-based mask blank and a mask obtained therefrom will be referred to as a tantalum-based mask).

As the mask blank formed with the thin film made of the chromium-based material, there was prepared a binary mask blank having on a transparent substrate a laminated structure of a light-shielding layer comprising a CrCON film (thickness: 38.5 nm) substantially composed of chromium, oxygen, nitrogen, and carbon and a CrON film (thickness: 16.5 nm) substantially composed of chromium, oxygen, and nitrogen, and a CrCON antireflection layer (thickness: 14 nm) substantially composed of chromium, oxygen, nitrogen, and carbon (hereinafter, this binary mask blank will be referred to as a chromium-based mask blank and a mask obtained therefrom will be referred to as a chromium-based mask).

With respect to the above-mentioned two kinds of binary mask blanks, an alkaline cleaning liquid containing a surfactant was supplied to the mask blank surfaces to carry out surface cleaning for the purpose of removing foreign matter (particles) adhering to the antireflection layers and foreign matter (particles) incorporated in the light-shielding layers and the antireflection layers.

The surface-cleaned mask blank surfaces were subjected to a defect inspection using a mask blank defect inspection apparatus (M1350: manufactured by Lasertec Corporation). As a result, no defects such as particles or pinholes were observed on the thin film surface of either of the mask blanks.

Then, transfer masks were manufactured using the two kinds of mask blanks subjected to surface cleaning in the same manner as described above. With respect to the tantalum-based mask blank, a resist pattern was formed on the mask blank surface and then dry etching with a fluorine-based (CF₄) gas was carried out using the resist pattern as a mask, thereby patterning the antireflection layer. Then, dry etching with a chlorine-based (Cl₂) gas was carried out using a pattern of the antireflection layer as a mask, thereby patterning the light-shielding layer. Finally, the resist pattern was removed so that a transfer mask (tantalum-based mask) was manufactured.

On the other hand, with respect to the chromium-based mask blank, a resist pattern was formed on the mask blank surface and then dry etching with a mixed gas of chlorine-based (Cl₂) gas and oxygen (O₂) gas was carried out using the resist pattern as a mask, thereby patterning the antireflection layer and the light-shielding layer. Finally, the resist pattern was removed so that a transfer mask (chromium-based mask) was manufactured.

The obtained two kinds of transfer masks were subjected to a defect inspection using a mask defect inspection apparatus (manufactured by KLA-Tencor Corporation). As a result, it was confirmed that many (more than 50) micro black defects were present on the tantalum-based mask. On the other hand, micro black defects were hardly observed on the chromium-based mask (the number of defects that could practically be corrected by a mask defect correction technique). Even if UV treatment, ozone treatment, or heat treatment was carried out for the purpose of removing dirt or the like of the mask blank before forming a resist film, those micro black defects were likewise observed on the tantalum-based mask.

Even if the antireflection layer and the light-shielding layer were patterned at a time by dry etching using a fluorine-based (CF₄) gas, those micro black defects were likewise observed on the tantalum-based mask.

The micro black defect of the tantalum-based mask detected by the defect inspection was subjected to cross-sectional observation in bright field using a scanning transmission electron microscope (STEM: Scanning Transmission Electron Microscope). The cross-sectional observation was carried out by coating a platinum alloy over the entire surface of the transparent substrate formed with the thin film pattern.

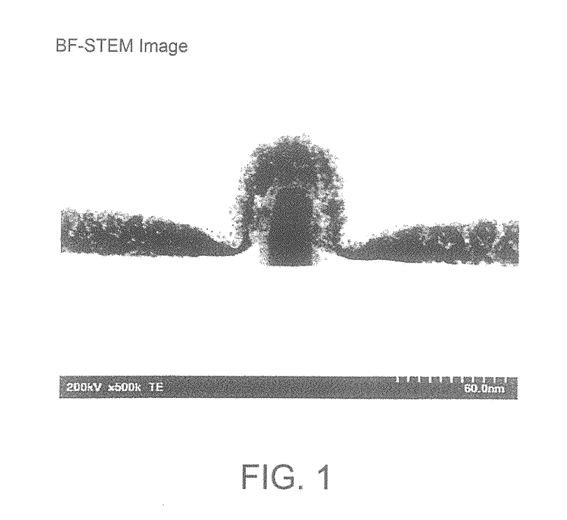

As a result, it was confirmed that the height of the micro black defect was approximately equal to the thickness of the laminated film of the light-shielding layer and the antireflection layer. More specifically, it was confirmed that the micro black defect was a stacked structure in which a substance considered to be a surface oxide having a thickness of 5 to 10 nm was stacked on a core having a width of about 23 nm and a height of about 43 nm (see FIG. 1).

From these results, the possibility was considered that the occurrence of the micro black defects was caused by adhesion of a substance, which becomes a factor to cause inhibition of the etching, to the surface of the thin film made of the tantalum-based material of the tantalum-based mask blank in a state (thickness) where the substance was difficult to detect even by the newest mask blank defect inspection apparatus. Specifically, as such an etching inhibition factor (i.e., a substance that causes production of the etching inhibitor), calcium (Ca), aluminum (Al), magnesium (Mg), or its compound was considered. This is because such a substance forms a compound such as calcium fluoride (boiling point: 2500° C.), magnesium fluoride (boiling point: 1260° C.), aluminum fluoride (boiling point: 1275° C.), calcium chloride (boiling point: 1600° C.), or magnesium chloride (boiling point: 1412° C.) when the thin film is dry-etched by the fluorine-based gas or the chlorine-based gas, and the formed compound serves as an etching inhibitor.

Then, in order to confirm whether or not the reason for the occurrence of the large difference between the numbers of the micro black defects on the transfer masks manufactured from the tantalum-based mask blank and the chromium-based mask blank was due to the etching inhibitor, an examination was made on the presence of the etching inhibition factor, which was not detected by the mask blank defect inspection apparatus, on the mask blank surfaces.

Specifically, five mask blanks were prepared for each of the above-mentioned two kinds of mask blanks (tantalum-based mask blank and chromium-based mask blank) and subjected to surface cleaning with the alkaline cleaning liquid. Then, a surface of a thin film of each mask blank was analyzed by time-of-flight secondary ion mass spectrometry (TOF-SIMS: Time-Of-Flight Secondary Ion Mass Spectrometry). In this event, the TOF-SIMS measurement conditions were such that the primary ion species was Bi₃⁺⁺, the primary accelerating voltage was 30 kV, the primary ion current was 3.0 nA, the primary ion irradiation region was a square region with a side of 200 μm, and the secondary ion measurement range was 0.5 to 3000 m/z. The measurement conditions were the same for all the mask blanks.

As a result, at least one or more kinds of ions of calcium, magnesium, and aluminum each as a substance which becomes a factor to cause inhibition of etching were detected on the surface of the thin film of any of the tantalum-based mask blanks. When calcium, magnesium, and/or aluminum was detected, the normalized secondary ion intensity thereof was greater than 1.0×10⁻³ in any of them.

On the other hand, in any of the chromium-based mask blanks, the normalized secondary ion intensity of ions of calcium, magnesium, and/or aluminum each as a substance which becomes a factor to cause inhibition of etching was minimum (less than 1.0×10⁻⁴).

As described above, since the thickness of the etching inhibition factor presumed to be adhering to the surface of the thin film of the tantalum-based mask blank is thin, it is difficult to detect it by the mask blank defect inspection apparatus. It is not impossible to specify a portion, where the etching inhibition factor is adhering, by scanning the entire surface of the thin film using an atomic force microscope (AFM), but the detection takes an enormous time. In view of this, two thin films each having a thickness of 100 nm and made of a chromium-based material with only a small possibility of adhesion of the etching inhibition factor were laminated on the thin film (tantalum-based film) of the tantalum-based mask blank subjected to the surface cleaning with the cleaning liquid. By this, if there is a convex portion, where the etching inhibition factor is present, on the thin film of the tantalum-based material, the height of the convex portion relatively increases due to the so-called decoration effect so that it is possible to detect it as a convex defect by the mask blank defect inspection apparatus.

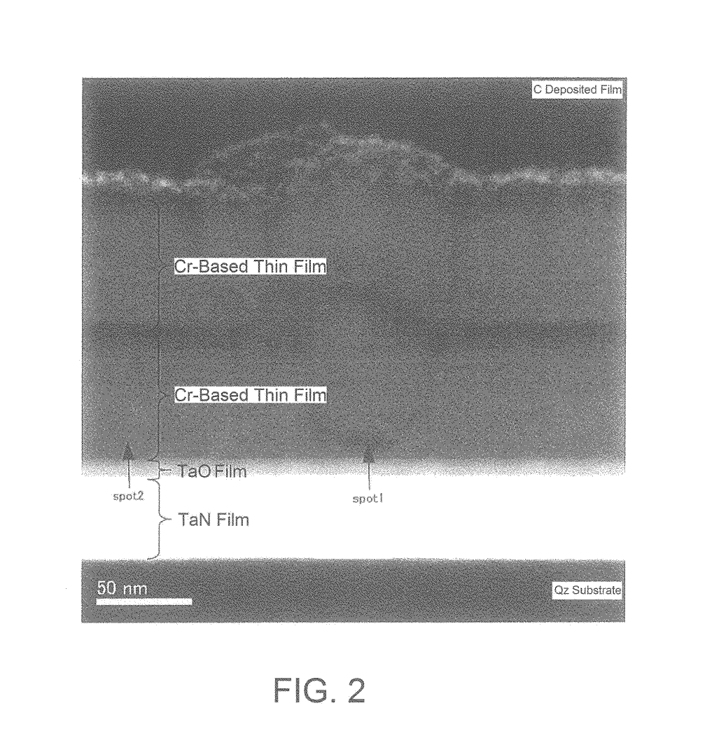

Using this technique, a defect inspection was carried out using the mask blank defect inspection apparatus, thereby specifying the positions of all convex defects. A plurality of the specified convex defects were subjected to cross-sectional observation in dark field using a scanning transmission electron microscope (STEM: Scanning Transmission Electron Microscope). As a result, it was confirmed that a layer of the etching inhibition factor was formed on the surface (see FIG. 2). In this event, an element forming the etching inhibition factor was also analyzed using an energy dispersive X-ray spectrometer (EDX) attached to STEM. The analysis by EDX was carried out for a portion on the surface of the tantalum-based thin film where the presence of the etching inhibition factor was confirmed (a portion indicated by symbol spot1 in FIG. 2) and, as reference data, for a portion on the surface of the tantalum-based thin film where the presence of the etching inhibition factor was not confirmed (a portion indicated by symbol spot2 in FIG. 2). As a result, the detection intensity of Ca (calcium) and O (oxygen) was high at the spot1 portion while the detection intensity of Ca (calcium) was very small at the spot2 portion. From this analysis result, it can be presumed that a layer of a substance containing calcium as the etching inhibition factor is present at the spot1 portion.

Also with respect to the chromium-based mask blank, thin films made of a chromium-based material were laminated in the same manner and then a defect inspection was carried out using the mask blank defect inspection apparatus. Cross-sectional observation by STEM and element specification by EDX were carried out in the same manner for a detected convex defect, but no such a layer as described above was found.

From the TOF-SIMS and STEM results described above, it has been made clear that the reason for the occurrence of the large difference between the numbers of the micro black defects on the transfer masks manufactured from the tantalum-based mask blank and the chromium-based mask blank is due to the difference between the numbers of portions, where the etching inhibition factor is adhering, of those mask blanks.

As a result of various verifications described above, it is conjectured that the frequent occurrence of micro black defects when the transfer mask was manufactured from the tantalum-based mask blank was caused in the following manner.

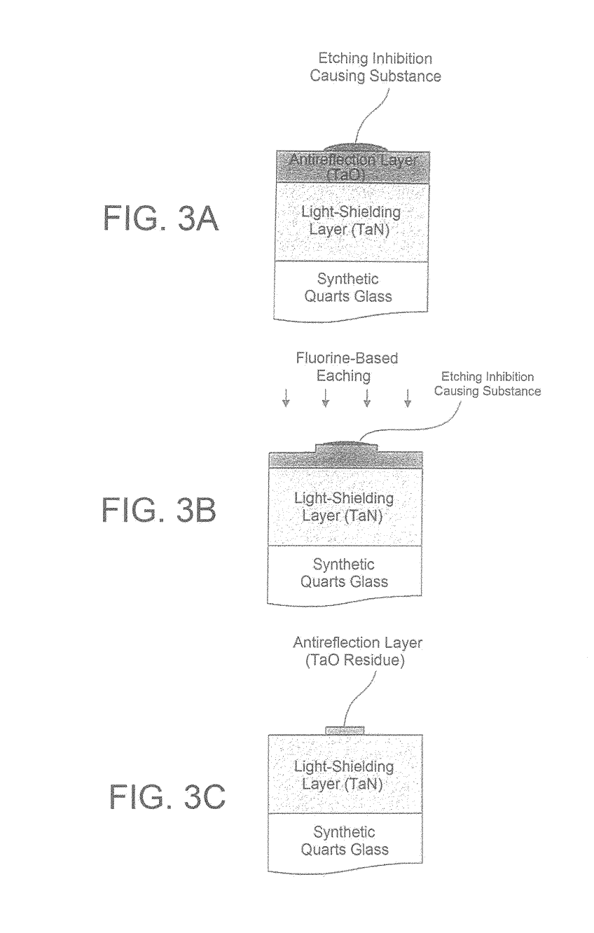

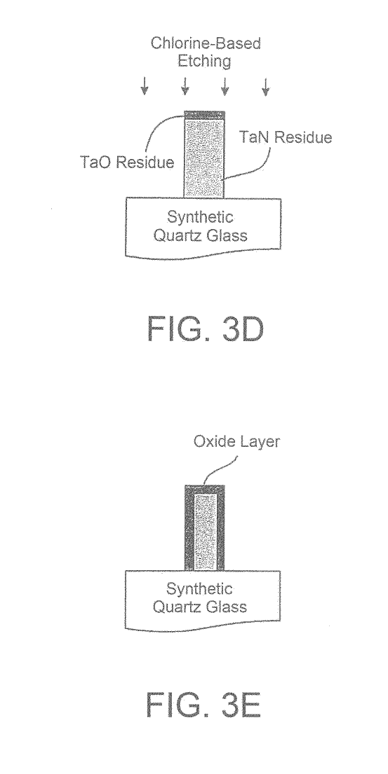

(1) An etching inhibition factor such as calcium is firmly adhering to a surface of a thin film of a mask blank. Since the thickness of this etching inhibition factor is extremely thin, it is difficult to detect it even by the newest mask blank defect inspection apparatus (FIG. 3A).

(2) An antireflection layer (TaO) at the thin film surface of the mask blank is patterned by dry etching using a fluorine-based gas. In this event, calcium adhering to the surface of the antireflection layer and the fluorine-based gas react with each other, thereby forming an etching inhibitor made of calcium fluoride (FIG. 3B). Since the calcium fluoride has a high boiling point and is thus hardly etched even by the fluorine-based gas, it acts as the etching inhibitor. This etching inhibitor serves as a mask so that the antireflection layer (TaO) partially remains without being etched (FIG. 3C).

(3) A light-shielding layer (TaN) is patterned by dry etching using a chlorine-based gas. In this event, since the etching rate of TaO with the chlorine-based gas is significantly lower than that of TaN, the remaining antireflection layer serves as a mask so that the light-shielding layer (TaN) partially remains without being etched. By this, a micro black defect core is formed (FIG. 3D).

(4) Thereafter, a surface of the micro black defect core is oxidized to thereby form an oxide layer around the core so that a micro black defect is formed on a surface of a substrate (synthetic quartz glass) (FIG. 3E).

While the mechanism of the occurrence of the micro black defect has been described in the case of calcium, since the possibility is high that magnesium or aluminum as an etching inhibition factor also reacts with fluorine, chlorine, or the like contained in an etching gas to form an etching inhibitor, it is considered that magnesium or aluminum generates a micro black defect by the same mechanism as described above. In dry etching using a chlorine-based gas, calcium or magnesium as the etching inhibition factor reacts with the chlorine-based gas to form calcium chloride or magnesium chloride. Since these chlorides also have high boiling points and are thus hardly dry-etched, they can be etching inhibitors. The etching inhibition factor represents a material that reacts with fluorine (F), chlorine (CI), or the like contained in a dry etching gas to produce an etching inhibitor.

As a result of the test and study described above, the conclusion has been reached that the following structure is satisfactory as a mask blank that can suppress the occurrence of micro black defects on a transfer mask.

Specifically, the mask blank of this invention is a mask blank having a structure in which a thin film is formed on a substrate, wherein the thin film is made of a material containing one or more elements selected from tantalum, tungsten, zirconium, hafnium, vanadium, niobium, nickel, titanium, palladium, molybdenum, and silicon, and wherein the normalized secondary ion intensity of at least one or more ions selected from a calcium ion, a magnesium ion, and an aluminum ion is 1.0×10⁻³ or less when a surface of the thin film is measured by time-of-flight secondary ion mass spectrometry (TOF-SIMS) under measurement conditions of a primary ion species of Bi₃⁺⁺, a primary accelerating voltage of 30 kV, and a primary ion current of 3.0 nA.

In consideration of the above-mentioned results of measuring the surfaces of the thin films by TOF-SIMS, in order to suppress the number of micro black defects, which occur when a transfer mask is manufactured, to 50 or less, the normalized secondary ion intensity of at least one or more ions selected from a calcium ion, a magnesium ion, and an aluminum ion should be 1.0×10⁻³ or less when the surface of the thin film is measured by TOF-SIMS. In order to further suppress the number of micro black defects which occur when a transfer mask is manufactured (e.g. to 40 or less), the normalized secondary ion intensity of at least one or more ions selected from a calcium ion, a magnesium ion, and an aluminum ion is preferably 5.0×10⁻⁴ or less when the surface of the thin film is measured by TOF-SIMS. Further preferably, the normalized secondary ion intensity of at least one or more ions selected from a calcium ion, a magnesium ion, and an aluminum ion is 1.0×10⁻⁴ or less when the surface of the thin film is measured by TOF-SIMS.

As another measurement condition for the measurement of the surface of the thin film by TOF-SIMS, the primary ion irradiation region is preferably a square region with a side of 200 μm. Further, the secondary ion measurement range is preferably 0.5 to 3000 m/z.

More preferably, the mask blank is configured to be a mask blank having a structure in which a thin film is formed on a substrate, wherein the thin film is made of a material containing one or more elements selected from tantalum, tungsten, zirconium, hafnium, vanadium, niobium, nickel, titanium, palladium, molybdenum, and silicon, and wherein the normalized secondary ion intensity of a calcium ion, a magnesium ion, and an aluminum ion is 1.0×10⁻³ or less when a surface of the thin film is measured by time-of-flight secondary ion mass spectrometry (TOF-SIMS) under measurement conditions of a primary ion species of Bi₃⁺⁺, a primary accelerating voltage of 30 kV, and a primary ion current of 3.0 nA. Further, the normalized secondary ion intensity of a calcium ion, a magnesium ion, and an aluminum ion is preferably 5.0×10⁻⁴ or less and particularly preferably 1.0×10⁻⁴ or less when the surface of the thin film is measured by TOF-SIMS.

In the above-mentioned mask blank, the thin film formed on the substrate is preferably made of a material containing one or more metals selected from tantalum (Ta), tungsten (W), zirconium (Zr), hafnium (Hf), vanadium (V), niobium (Nb), nickel (Ni), titanium (Ti), palladium (Pd), molybdenum (Mo), and silicon (Si). In terms of controlling the optical properties and the etching characteristics, the material preferably contains oxygen, nitrogen, carbon, boron, hydrogen, fluorine, or the like. With the thin film made of such a material, it is possible to form a transfer pattern adapted to the semiconductor design rule DRAM half-pitch 32 nm generation and beyond by dry etching using a fluorine-based gas or a chlorine-based gas substantially free of oxygen. For example, it is possible to form an auxiliary pattern such as SRAF (Sub-Resolution Assist Feature) with a line width of 40 nm or less which is often formed in a transfer pattern adapted to the DRAM half-pitch 32 nm generation and beyond.

As the etching gas containing fluorine (fluorine-based gas), there can be cited CHF₃, CF₄, SF₆, C₂F₆, C₄F₈, or the like. As the etching gas containing chlorine (chlorine-based gas), there can be cited Cl₂, SiCl₄, CHCl₃, CH₂Cl₂, CCl₄, or the like. Alternatively, a mixed gas of such a fluorine-based gas or such a chlorine-based gas and a gas such as He, H₂, Ar, or C₂H₄ can be used as a dry etching gas.

Herein, in the case of dry etching using as an etching gas a fluorine-based gas or a chlorine-based gas substantially free of oxygen, it strongly tends to be ion-based dry etching. In the case of the ion-based dry etching, it is easy to control the dry etching to be anisotropic so that there is an excellent effect that it is possible to achieve high verticality of a sidewall of a pattern formed in a thin film. However, in the case of the anisotropic dry etching, since etching in a pattern sidewall direction is suppressed, if an etching inhibition factor such as calcium or an etching inhibitor produced therefrom is present on the thin film, it is difficult to remove it by the dry etching.

On the other hand, in the case of dry etching using as an etching gas a mixed gas of oxygen gas and chlorine-based gas, it strongly tends to be radical-based dry etching. In the case of the radical-based dry etching, it is difficult to control the dry etching to be anisotropic so that it is not easy to achieve high verticality of a sidewall of a pattern formed in a thin film. However, in the case of the dry etching having such an isotropic tendency, since etching in a pattern sidewall direction also proceeds relatively easily, even if an etching inhibition factor such as calcium or an etching inhibitor produced therefrom is present on the thin film, it is relatively easily removed during the dry etching.

In the above-mentioned test, the etching gases used in the dry etching for forming the pattern in the thin films made of the tantalum-based materials of the tantalum-based mask blank were the fluorine-based gas and the chlorine-based gas substantially free of oxygen. Therefore, the dry etching strongly tends to be ion-based so that an etching inhibitor is difficult to remove. Further, any of the above-listed thin films of the mask blanks, in addition to the tantalum-based mask blank, is also made of the material that can be etched by ion-based dry etching, and therefore, it can be said that if an etching inhibition factor is present on the thin film surface, micro black defects tend to occur in the dry etching. On the other hand, in the above-mentioned test, the etching gas used in the dry etching for forming the pattern in the thin films made of the chromium-based materials of the chromium-based mask blank was the mixed gas of chlorine-based gas and oxygen gas. Therefore, the dry etching strongly tends to be radical-based so that an etching inhibitor is relatively easily removed. This can also be cited as one of the reasons that the number of micro black defects which occur when the transfer mask is manufactured from the chromium-based mask blank is small.

From the reasons described above, the thin film of the mask blank is preferably provided for forming a thin film pattern by dry etching using an etching gas containing fluorine or an etching gas containing chlorine. In particular, among etching gases containing chlorine, an etching gas containing chlorine and substantially free of oxygen is preferable. Herein, the etching gas containing chlorine and substantially free of oxygen means that the oxygen concentration in such an etching gas is 5 vol % or less and more preferably 3 vol % or less. It is more preferable that the above-mentioned thin film be formed into a pattern by ion-based etching.

Preferably, the material of the thin film of the mask blank is a material containing tantalum. Further, when the thin film is made of the material containing tantalum, it is preferable that an oxide layer be formed as a surface layer of the thin film, wherein the oxide layer contains more oxygen than a portion other than the surface layer. As an example of such a thin film, there can be cited a thin film in which an oxide layer (TaO, particularly a highly oxidized layer in which the oxygen content is 60 at % or more and the ratio of the presence of Ta₂O₅ bonds is high) is formed as a surface layer of a tantalum nitride film (TaN film) or a tantalum film (Ta film). Many hydroxyl groups (OH groups) are present on a surface of a surface layer of the oxide layer containing tantalum. When many hydroxyl groups are present on the surface, an etching inhibition factor such as calcium tends to adhere thereto for a reason described later and therefore the effect of this invention can be obtained more remarkably.

Preferably, the thin film made of the material containing tantalum of the mask blank has a laminated structure of a lower layer and an upper layer from the substrate side and the upper layer contains oxygen. More preferably, the thin film is a laminated film in which a lower layer made of a material containing tantalum and nitrogen and an upper layer made of a material containing tantalum and oxygen are laminated. In this case, a highly oxidized layer which contains more oxygen than the other region in the upper layer (e.g. the oxygen content is 60 at % or more) and in which the ratio of the presence of Ta₂O₅ bonds is high may be formed as a surface layer of the upper layer. The ratio of the presence of hydroxyl groups (OH groups) tends to be high on a surface of an oxide layer containing tantalum or a tantalum oxide film. When many hydroxyl groups are present on the surface, an etching inhibition factor such as calcium tends to adhere thereto for a reason described later and therefore the effect of this invention can be obtained more remarkably. Herein, as the material containing tantalum and nitrogen, there can be cited TaN, TaBN, TaCN, TaBCN, or the like. The material may contain an element other than tantalum or nitrogen. As the material containing tantalum and oxygen, there can be cited TaO, TaBO, TaCO, TaBCO, TaON, TaBON, TaCON, TaBCON, or the like. The material may contain an element other than tantalum or oxygen.

Alternatively, the thin film made of the material containing tantalum of the mask blank may have a structure in which a lower layer made of only tantalum and an upper layer made of a material containing tantalum and oxygen are laminated from the substrate side. In particular, the etching rate of a material made of only tantalum, which is a material free of oxygen and nitrogen, is higher than that of a material containing tantalum and nitrogen in dry etching using an etching gas containing chlorine and substantially free of oxygen. With respect to the upper layer made of the material containing tantalum and oxygen, it is the same as the upper layer described above.

Alternatively, the thin film made of the material containing tantalum of the mask blank may have a structure in which a lower layer made of a material containing tantalum and silicon and an upper layer made of a material containing tantalum and oxygen are laminated from the substrate side. The crystal state of the material containing tantalum and silicon can be finer crystalline or more amorphous than that of a material containing tantalum and nitrogen. By adding silicon to tantalum, the optical density (extinction coefficient) for exposure light can be made higher than that of a material made of only tantalum. In particular, in the case of a material made of only tantalum and silicon, the extinction coefficient becomes maximum when the mixing ratio between tantalum (Ta) and silicon (Si) in the material is Ta:Si=1:2 (at % ratio) so that the thickness of the lower layer can be significantly reduced.

On the other hand, by adding silicon to tantalum, the etching rate can be made higher than that of the material made of only tantalum in dry etching using an etching gas containing chlorine and substantially free of oxygen. In particular, in the case of the material made of only tantalum and silicon, the etching rate thereof increases as the content of silicon in the material increases and, when the mixing ratio between tantalum (Ta) and silicon (Si) in the material is Ta:Si=1:2 (at % ratio), the etching rate thereof becomes maximum.

In consideration of these, the ratio [%] of the content [at %] of tantalum to the total content [at %] of tantalum and silicon in the material forming the lower layer is preferably 20% or more, more preferably 30% or more, and further preferably 33% or more. Further, the ratio [%] of the content [at %] of tantalum to the total content [at %] of tantalum and silicon in the material forming the lower layer is preferably 95% or less, more preferably 90% or less, and further preferably 85% or less. With respect to the upper layer made of the material containing tantalum and oxygen, it is the same as the upper layer described above.

As one cause that an etching inhibition factor such as calcium, magnesium, or aluminum adheres to the surface of the thin film of the mask blank, there can be cited a detergent (surfactant) that is used when carrying out surface cleaning of the thin film. There are instances where a surfactant for use in surface cleaning of a mask blank contains calcium ions (Ca²⁺), magnesium ions (Mg²⁺), aluminum ions (Al³⁺), and aluminum hydroxide ions (Al(OH)₄⁻) as impurities depending on its manufacturing method and pH. Since these are ionized, it is difficult to remove them. It is considered that calcium or the like detected by TOF-SIMS as described above was contained in the surfactant contained in the cleaning liquid which was used this time.

As described above, after the cleaning using the alkaline cleaning liquid containing the surfactant, calcium or the like as the etching inhibition factor was detected on the surface of the tantalum-based mask blank. On the other hand, calcium or the like was hardly detected on the surface of the chromium-based mask blank. Hereinbelow, the cause of the occurrence of such a difference will be considered. The following consideration is based on a presumption by the present inventors at the time of filing this application and by no means limits the scope of this invention.

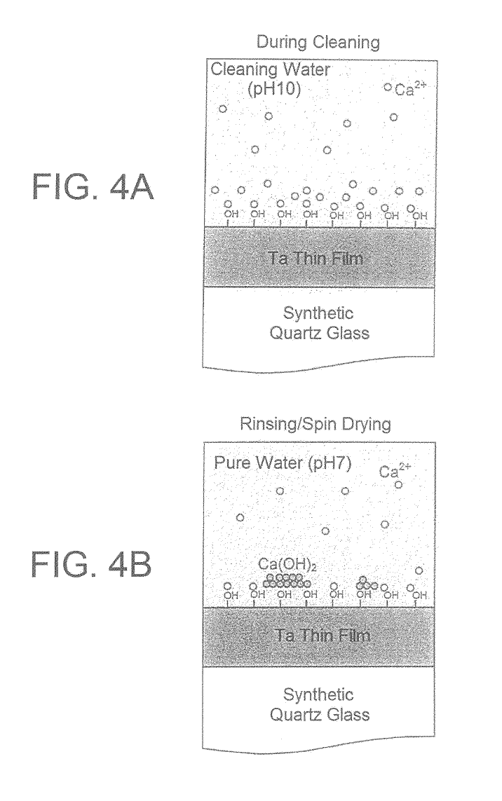

Many hydroxyl groups (OH groups) are present on a surface of a tantalum-based mask blank. Calcium ions (Ca²⁺) or magnesium ions (Mg²⁺) contained in a cleaning liquid are attracted to these hydroxyl groups (FIG. 4A). Then, upon rinsing with pure water for washing away the cleaning liquid after cleaning with the cleaning liquid, the liquid covering the surface of the mask blank rapidly changes from alkaline (pH10) to neutral (around pH7). As a result, the calcium ions or the magnesium ions attracted to the surface of the mask blank tend to be precipitated as calcium hydroxide (Ca(OH)₂) or magnesium hydroxide (Mg(OH)₂) on the film surface (FIG. 4B). It is considered that this calcium hydroxide or magnesium hydroxide serves as an etching inhibition factor on the surface of the mask blank.

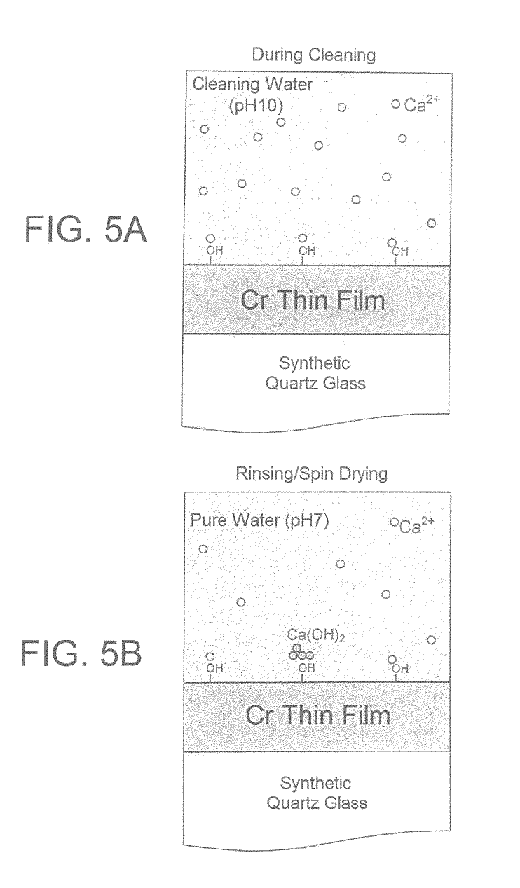

On the other hand, only a small number of hydroxyl groups (OH groups) are present on a surface of a chromium-based mask blank. Accordingly, calcium ions or magnesium ions contained in a cleaning liquid are not so attracted to the surface of the mask blank. Since the concentration of calcium or the like as an impurity originally contained in the cleaning liquid, itself, is low, the concentration of calcium ions or magnesium ions in the vicinity of the film surface is extremely low (FIG. 5A). As a result, upon rinsing with pure water for washing away the cleaning liquid after cleaning with the cleaning liquid, the calcium ions or the magnesium ions attracted to the surface of the mask blank are washed away from the film surface before becoming calcium hydroxide or magnesium hydroxide or, even if those ions become calcium hydroxide or magnesium hydroxide, only a small number of molecules, that do not inhibit etching, are precipitated on the film surface (FIG. 5B).

In the above-mentioned mask blank, the substrate is preferably a glass substrate having transparency for exposure light and the thin film is preferably for use in forming a transfer pattern when manufacturing a transfer mask from this mask blank. The mask blank of this structure is also called a transmission mask blank. Further, the transfer mask manufactured from this transmission mask blank is also called a transmission mask. In the case of the mask blank of this structure, as an example of the thin film for forming the transfer pattern, there can be cited a light-shielding film having a function of shielding exposure light, an antireflection film having a function of suppressing the surface reflection in order to suppress multiple reflection with respect to a transfer target, a phase shift film having a function of providing a predetermined transmittance and a predetermined phase difference for exposure light in order to enhance the pattern resolution, or the like. As an example of the thin film for forming the transfer pattern, there is also included a semi-transmissive film that provides a predetermined transmittance for exposure light, but does not provide a phase difference that produces a phase shift effect. The mask blank having such a semi-transmissive film is mainly used for manufacturing an enhancer phase shift mask. The thin film may be in the form of a single-layer film or a laminated film in which a plurality of the above-mentioned thin films are laminated. A transfer mask manufactured from the mask blank having the above-mentioned thin film for forming the transfer pattern is adapted to be applied with ArF excimer laser light, KrF excimer laser light, or the like as exposure light.

In the above-mentioned mask blank, a multilayer reflective film having a function of reflecting exposure light is preferably provided between the substrate and the thin film and the thin film is preferably for use in forming a transfer pattern when manufacturing a transfer mask from this mask blank. The mask blank of this structure is also called a reflective mask blank. Further, the transfer mask manufactured from this reflective mask blank is also called a reflective mask. In this reflective mask blank, as an example of the thin film for forming the transfer pattern, there can be cited an absorber film having a function of absorbing exposure light, a reflection reducing film that reduces the reflection of exposure light, a buffer layer for preventing etching damage to the multilayer reflective film in patterning the absorber film, or the like. The reflective mask is included as a transfer mask of this invention. This reflective mask is preferably applied with EUV (Extreme Ultra Violet) light as exposure light. While the EUV light is light (electromagnetic wave) having a wavelength between 0.1 nm and 100 nm, the light (electromagnetic wave) having a wavelength of 13 nm to 14 nm is particularly used.

As a structure of the multilayer reflective film of the reflective mask blank, use is often made of a film structure in which, for example, given that a silicon film (Si film, thickness 4.2 nm) and a molybdenum film (Mo film, thickness 2.8 nm) form one cycle, these films are laminated by a plurality of cycles (20 cycles to 60 cycles, preferably about 40 cycles). A protective film (e.g. Ru, RuNb, RuZr, RuY, RuMo, or the like) for protecting the multilayer reflective film may be provided between the multilayer reflective film and the absorber film or the buffer layer.

As a film forming the mask blank, an etching mask film (or a hard mask film) that serves as an etching mask (hard mask) in etching an underlying film may be provided in addition to the above-mentioned thin film to be the transfer pattern. Alternatively, the thin film to be the transfer pattern may be in the form of a laminated film and an etching mask (hard mask) may be provided as part of the laminated film.

In the case of the transmission mask blank, the material of the substrate is satisfactory if it is a material that can transmit exposure light and, for example, a synthetic quartz glass can be cited. In the case of the reflective mask blank, the material of the substrate is satisfactory if it is a material that can prevent thermal expansion due to absorption of exposure light and, for example, there can be cited a TiO₂—SiO₂ low-expansion glass, a crystallized glass precipitated with β-quartz solid solution, single crystal silicon, SiC, or the like.

Preferably, the transfer mask is manufactured by a manufacturing method comprising a process of forming a transfer pattern by dry-etching the thin film of the mask blank. Further, more preferably, the dry etching in this manufacturing method of the transfer mask uses an etching gas containing fluorine or an etching gas containing chlorine.

In the case of dry-etching the thin film of the mask blank using the etching gas containing fluorine or the etching gas containing chlorine, there are manganese, iron, and nickel as etching inhibiting substances in addition to the above-listed substances. Therefore, in the mask blank, the normalized secondary ion intensity of at least one or more ions selected from a manganese ion, an iron ion, and a nickel ion is preferably 1.0×10⁻³ or less when the surface of the thin film is measured by time-of-flight secondary ion mass spectrometry (TOF-SIMS) under measurement conditions of a primary ion species of Bi₃⁺⁺, a primary accelerating voltage of 30 kV, and a primary ion current of 3.0 nA. Further, the normalized secondary ion intensity is more preferably 5.0×10⁻⁴ or less and particularly preferably 1.0×10⁻⁴ or less.

As described above, the large cause that the etching inhibition factor adheres to the surface of the thin film of the mask blank is the surface cleaning using the alkaline cleaning liquid containing the surfactant, which is carried out, for example, after forming the thin film on the substrate. It is not easy to remove, from this cleaning liquid, the etching inhibition factor once incorporated into the cleaning liquid due to its manufacturing method even when the etching inhibition factor is present in a solid state, and such removal is difficult when it is present in an ionic state. Therefore, as the cleaning liquid for cleaning the thin film of the mask blank, it is most preferable to use a liquid in which etching inhibition factors such as calcium, magnesium, and aluminum are below a detection limit (e.g. DI water).

However, particularly in the case of the alkaline cleaning liquid containing the surfactant, it is difficult to avoid incorporation of these etching inhibition factors. Surfaces of thin films of mask blanks were cleaned using a plurality of cleaning liquids with different etching inhibition factor concentrations, then the thin films were dry-etched and the numbers of occurrences of micro black defects were measured. As a result, it was confirmed that if the etching inhibition factor concentration in the cleaning liquid is 0.3 ppb or less, the number of occurrences of micro black defects could be suppressed to a level with no problem in practical use. From the above, it is preferable to use a cleaning liquid with an etching inhibition factor concentration of 0.3 ppb or less in surface cleaning which is carried out for the thin film of the mask blank.

When the thin film of the mask blank is made of a material with low adhesion to a resist film (particularly a material containing Si), a treatment for reducing the surface energy of the mask blank may be carried out in order to prevent the occurrence of stripping or collapse of a fine pattern formed in the resist film. In this surface treatment, use is made of a surface treatment liquid for alkyl-silylating the surface of the mask blank, such as hexamethyldisilazane (HMDS) or another organic silicon-based surface treatment liquid. Also in this surface treatment liquid, the etching inhibition factor concentration is preferably below the detection limit. However, if the etching inhibition factor concentration in the surface treatment liquid is 0.3 ppb or less, the mask blank of this invention can be manufactured.

The etching inhibition factor concentration in each of the above-mentioned treatment liquids can be measured by inductively coupled plasma-mass spectroscopy (ICP-MS: Inductively Coupled Plasma-Mass Spectroscopy) for the treatment liquid immediately before being supplied to the surface of the mask blank and represents the total concentration of elements (excluding those below the detection limit) detected by ICP-MS. By ICP-MS, it is possible to specify an element, but it is difficult to specify a bonding state between elements. Therefore, for example, the detected value of the calcium concentration in the liquid represents a concentration calculated in terms of the total amount of calcium and calcium compounds (the same shall apply to the case of magnesium or aluminum).

Next, mask blanks of this invention will be described with reference to Examples and Comparative Examples.

### Example 1, Comparative Example 1

There were prepared a plurality of synthetic quartz glass substrates (about 152.1 mm×about 152.1 mm×about 6.25 mm) whose main surfaces and end faces were precision-polished. Then, a thin film made of a material containing tantalum was formed on the main surface of each glass substrate. Specifically, a thin film in which a lower layer made of TaN (Ta:N=84:16 at % ratio) and having a thickness of 42 nm and an upper layer made of TaO (Ta:O=42:58 at % ratio) and having a thickness of 9 nm were laminated from the glass substrate side was formed. In this manner, there were prepared a plurality of binary mask blanks for ArF excimer laser exposure adapted to the semiconductor design rule DRAM half-pitch 32 nm.

Five binary mask blanks were selected from the plurality of prepared binary mask blanks and then surfaces of the thin films of the mask blanks were respectively subjected to surface cleaning (spin cleaning) using cleaning liquids A to E shown in Table 1. Further, the mask blanks (mask blanks A1 to E1) surface-cleaned with the respective cleaning liquids were subjected to rinsing (spin cleaning) using DI water and then to spin drying.

The normalized secondary ion intensity of a calcium ion was measured by TOF-SIMS for the surfaces of the thin films of the mask blanks after the spin drying. The results are shown in Table 1. Measurement conditions in this TOF-SIMS were as follows.

Primary Ion Species: Bi₃⁺⁺

Primary Accelerating Voltage: 30 kV

Primary Ion Current: 3.0 nA

Primary Ion Irradiation Region: square region with a side of 200 μm

Secondary Ion Measurement Range: 0.5 to 3000 m/z

TABLE 1

| Cleaning Liquid | | Mask Blank | | |
|---|---|---|---|---|
| | Ca | | Normalized Secondary | Number of Black |
| | Concentration | | Ion Intensity | Defects in Mask |
| No. | [ppb] | No. | Ca | [count] |
| A | 0.8 | A1 | 9.2 × 10⁻³ | 131 |
| B | 0.4 | B1 | 1.7 × 10⁻³ | 76 |
| C | 0.3 | C1 | 8.2 × 10⁻⁴ | 43 |
| D | 0.2 | D1 | 4.1 × 10⁻⁴ | 31 |
| E | 0.1 | E1 | <1.0 × 10⁻⁴ | 12 |

Mask blanks A1 to E1 subjected to surface cleaning in the same manner as described above were separately prepared. A chemically amplified positive resist (PRL009: manufactured by FUJIFILM Electronic Materials Co., Ltd.) was spin-coated on a surface of each of the prepared mask blanks and then prebaking was carried out, thereby forming a resist film.

Then, the resist film was subjected to writing, development, and rinsing, thereby forming a resist pattern on the surface of the mask blank. Then, dry etching with a fluorine-based (CF₄) gas was carried out using the resist pattern as a mask, thereby patterning an upper layer to form an upper layer pattern (in this event, a lower layer was also partially etched). Then, dry etching with a chlorine-based (Cl₂) gas was carried out using the upper layer pattern as a mask, thereby patterning the lower layer to form a lower layer pattern. Finally, the resist pattern was removed, thereby forming a transfer mask.

With respect to each of the transfer masks thus obtained, a defect inspection was carried out in a transfer pattern forming region (132 mm×104 mm) using a mask defect inspection apparatus (manufactured by KLA-Tencor Corporation).

Table 1 shows the numbers of black defects detected on the respective transfer masks.

From the results described above, it is seen that it is possible to suppress the number of micro black defects, which occur when the transfer mask is manufactured, to 50 or less by selecting the mask blank in which the normalized secondary ion intensity of a calcium ion is 1.0×10⁻³ or less when the surface of the thin film of the mask blank is measured by TOF-SIMS under the above-mentioned measurement conditions.

### Example 2, Comparative Example 2

In the same manner as in Example 1 and Comparative Example 1, there were prepared a plurality of binary mask blanks for ArF excimer laser exposure adapted to the semiconductor design rule DRAM half-pitch 32 nm, each having a thin film in which a lower layer of TaN and an upper layer of TaO were laminated from the glass substrate side.

Five binary mask blanks were selected from the plurality of prepared binary mask blanks and then surfaces of the thin films of the mask blanks were respectively subjected to surface cleaning (spin cleaning) using cleaning liquids F to J shown in Table 2. Further, the mask blanks (mask blanks F1 to J1) surface-cleaned with the respective cleaning liquids were subjected to rinsing (spin cleaning) using DI water and then to spin drying.

The normalized secondary ion intensity of a magnesium ion was measured by TOF-SIMS for the surfaces of the thin films of the mask blanks after the spin drying. The results are shown in Table 2. Measurement conditions in this TOF-SIMS were the same as in Example 1 and Comparative Example 1.

TABLE 2

| Cleaning Liquid | | Mask Blank | | |
|---|---|---|---|---|
| | Mg | | Normalized Secondary | Number of Black |
| | Concentration | | Ion Intensity | Defects in Mask |
| No. | [ppb] | No. | Mg | [count] |
| F | 0.8 | F1 | 8.5 × 10⁻³ | 126 |
| G | 0.4 | G1 | 2.3 × 10⁻³ | 77 |
| H | 0.3 | H1 | 9.1 × 10⁻⁴ | 46 |
| I | 0.2 | I1 | 4.8 × 10⁻⁴ | 37 |
| J | 0.1 | J1 | <1.0 × 10⁻⁴ | 11 |

Mask blanks F1 to J1 subjected to surface cleaning in the same manner as described above were separately prepared. Using the prepared mask blanks, transfer masks were manufactured in the same manner as in Example 1 and Comparative Example 1. Further, with respect to each of the transfer masks thus obtained, a defect inspection was carried out in a transfer pattern forming region (132 mm×104 mm) using a mask defect inspection apparatus (manufactured by KLA-Tencor Corporation). Table 2 shows the numbers of black defects detected on the respective transfer masks.

From the results described above, it is seen that it is possible to suppress the number of micro black defects, which occur when the transfer mask is manufactured, to 50 or less by selecting the mask blank in which the normalized secondary ion intensity of a magnesium ion is 1.0×10⁻³ or less when the surface of the thin film of the mask blank is measured by TOF-SIMS under the above-mentioned measurement conditions.

### Example 3, Comparative Example 3

In the same manner as in Example 1 and Comparative Example 1, there were prepared a plurality of binary mask blanks for ArF excimer laser exposure adapted to the semiconductor design rule DRAM half-pitch 32 nm, each having a thin film in which a lower layer of TaN and an upper layer of TaO were laminated from the glass substrate side.

Five binary mask blanks were selected from the plurality of prepared binary mask blanks and then surfaces of the thin films of the mask blanks were respectively subjected to surface cleaning (spin cleaning) using cleaning liquids K to P shown in Table 3. Further, the mask blanks (mask blanks K1 to P1) surface-cleaned with the respective cleaning liquids were subjected to rinsing (spin cleaning) using DI water and then to spin drying.

The normalized secondary ion intensity of an aluminum ion was measured by TOF-SIMS for the surfaces of the thin films of the mask blanks after the spin drying. The results are shown in Table 3. Measurement conditions in this TOF-SIMS were the same as in Example 1 and Comparative Example 1.

TABLE 3

| Cleaning Liquid | | Mask Blank | | |
|---|---|---|---|---|
| | Al | | Normalized Secondary | Number of Black |
| | Concentration | | Ion Intensity | Defects in Mask |
| No. | [ppb] | No. | Al | [count] |
| K | 0.8 | K1 | 8.9 × 10⁻³ | 121 |
| L | 0.4 | L1 | 1.9 × 10⁻³ | 67 |
| M | 0.3 | M1 | 9.4 × 10⁻⁴ | 48 |
| N | 0.2 | N1 | 4.2 × 10⁻⁴ | 29 |
| P | 0.1 | P1 | <1.0 × 10⁻⁴ | 13 |

Mask blanks K1 to P1 subjected to surface cleaning in the same manner as described above were separately prepared. Using the prepared mask blanks, transfer masks were manufactured in the same manner as in Example 1 and Comparative Example 1. Further, with respect to each of the transfer masks thus obtained, a defect inspection was carried out in a transfer pattern forming region (132 mm×104 mm) using a mask defect inspection apparatus (manufactured by KLA-Tencor Corporation). The results are shown in Table 3.

From the results described above, it is seen that it is possible to suppress the number of micro black defects, which occur when the transfer mask is manufactured, to 50 or less by selecting the mask blank in which the normalized secondary ion intensity of an aluminum ion is 1.0×10⁻³ or less when the surface of the thin film of the mask blank is measured by TOF-SIMS under the above-mentioned measurement conditions.

1. A mask blank having a structure comprising a thin film on a substrate, wherein the thin film is made of a material containing one or more elements selected from tantalum, tungsten, zirconium, hafnium, vanadium, niobium, nickel, titanium, palladium, molybdenum, and silicon, and
wherein a normalized secondary ion intensity of at least one or more ions selected from a calcium ion, a magnesium ion, and an aluminum ion is 1.0×10⁻³ or less when a surface of the thin film is measured by time-of-flight secondary ion mass spectrometry (TOF-SIMS) under measurement conditions of a primary ion species of Bi₃⁺⁺, a primary accelerating voltage of 30 kV, and a primary ion current of 3.0 nA.

2. The mask blank according to claim 1, wherein the thin film is made of a material containing tantalum.

3. The mask blank according to claim 2, wherein the thin film comprises as a surface layer an oxide layer containing oxygen.

4. The mask blank according to claim 2, wherein the thin film comprises a laminated structure having a lower layer and an upper layer from a substrate side and the upper layer contains oxygen.

5. The mask blank according to claim 1, wherein the thin film is provided to form a thin film pattern by dry etching using an etching gas containing fluorine or an etching gas containing chlorine.

6. The mask blank according to claim 1, wherein the normalized secondary ion intensity is measured under a measurement condition that a primary ion irradiation region is a square region with a side of 200 μm.

7. The mask blank according to claim 1, wherein the at least one or more ions selected from the calcium ion, the magnesium ion, and the aluminum ion are substances each of which becomes a factor to cause inhibition of etching upon forming a pattern in the thin film by dry etching using an etching gas containing fluorine or an etching gas containing chlorine.

8. The mask blank according to claim 1,
wherein the substrate is a glass substrate having transparency for exposure light, and
wherein the thin film is used to form a transfer pattern upon manufacturing a transfer mask from the mask blank.

9. The mask blank according to claim 1,
wherein a multilayer reflective film having a function of reflecting exposure light is provided between the substrate and the thin film, and
wherein the thin film is used to form a transfer pattern upon manufacturing a transfer mask from the mask blank.

10. A method of manufacturing a transfer mask, comprising:
forming a transfer pattern by dry etching in the thin film of the mask blank according to claim 1.

11. The method of manufacturing a transfer mask according to claim 10, wherein the dry etching uses an etching gas containing fluorine or an etching gas containing chlorine.
